(19) United States
(12) Patent Application Publication
(10) Pub. No.: US 2026/0147369 A1
(43) Pub. Date: May 28, 2026

(54) VOLTAGE REFERENCE CIRCUIT

(71) Applicant: STMicroelectronics International N.V., Geneva (CH)

(72) Inventors: Carlo Curina, Lombardore (TO) (IT); Valerio Bendotti, Milano (IT)

(21) Appl. No.: 19/384,106

(22) Filed: Nov. 10, 2025

(30) Foreign Application Priority Data
Nov. 22, 2024 (IT) 102024000026421

(51) Int. Cl. G05F 3/18

(52) U.S. Cl. CPC G05F 3/185

(57) ABSTRACT

A voltage reference circuit for supplying a reference voltage, comprising a Zener circuitry configured to generate a Zener voltage and a temperature compensation circuit arrangement comprising a generator generating a temperature-depending current, and supplying at its output a current proportional or equal to the temperature-depending current to a Zener voltage compensation circuit comprising a compensation resistor, receiving current proportional or equal to the temperature-depending current, on which a compensation voltage is formed, the voltage reference circuit being configured to supply an output voltage that depends on the Zener voltage and the temperature compensation voltage, wherein the voltage reference circuit is configured to supply the output voltage as differential voltage between a first voltage and a second voltage, at least one of the first voltage and second voltage being taken from the Zener voltage compensation circuit.

### CROSS-REFERENCE TO RELATED APPLICATIONS

This application claims the benefit of Italian Application No. 102024000026421, filed on Nov. 22, 2024, which application is hereby incorporated herein by reference.

### TECHNICAL FIELD

The description relates to a voltage reference circuit comprising Zener circuitry and a temperature compensation network, which may be applied, e.g., to high voltage (HV) battery packs for BEVs (Battery Electric Vehicles) and PHEVs (Plug-in Hybrid Electric Vehicles), 48V battery packs for mild hybrid vehicles, backup energy storage systems, and uninterruptable power supplies (UPSs).

### BACKGROUND

A Zener voltage reference circuit exploits the intrinsic stability of the breakdown voltage of a Zener diode properly biased from which is subtracted a voltage, PTAT voltage compensation, ΔV_{X} coming from a PTAT current (Proportional To Absolute Temperature current), which is coming for instance from a bandgap reference, to get an almost flat temperature variation.

As shown in FIG. 1, where a Zener reference circuit 10, or regulator, is shown, a temperature compensation module, in particular a PTAT module 11, which comprises PTAT mirrors 111, 112, 113 mirroring the current of a PTAT current generator 15 supplying a PTAT current IPTAT, is coupled between a supply voltage, in particular a battery voltage VBAT, for instance from the battery of a BEV or PHEV, and a ground reference GND and has its two terminal outputs 11a and 11b coupled to a voltage divider 12, which comprises a first resistor, a compensation resistor Rₓ, on which is formed the PTAT voltage compensation, ΔV_{X}, in series with a second resistor R_{y} coupled to ground GND. The output 11a of the PTAT module 11 is coupled to a terminal of the first resistor Rₓ while the second output 11b is coupled to the central node of the divider 12, i.e., the node to which both the resistors Rₓ, R_{y} are coupled which forms the output of the divider 12, on which the compensated Zener voltage, V_{zener_comp}, is formed.

The divider 12 embodies a Zener voltage compensation circuit comprising the compensation resistor Rₓ, receiving the temperature depending current, i.e., PTAT current IPTAT, on which the compensation voltage ΔV_{X} is formed. A bias current generator 13 supplying a bias current I_{BIAS} is coupled between the supply voltage VBAT and output 11a, while a Zener diode 14, is coupled between the output 11 and ground GND, a Zener voltage drop V_{zener} occurring on the Zener diode 14.

On the compensation resistor Rₓ forms the voltage drop, or PTAT voltage compensation ΔV_{X}, which is originated from the temperature depending current, PTAT current IPTAT. The current mirrors 111, 112 in parallel receive the current IPTAT and have 1:k mirroring ratio, with k integer value equal or greater than one. The first mirror PMR1, with n-MOSFET type transistors coupled to ground GND, repeats the temperature depending current IPTAT to a mirror 113, p-MOSFET type transistors coupled to voltage supply VBAT with 1:1 mirroring ratio, which serves to mirror the current into node 11a. Mirror 112, also n-type, mirrors the PTAT current IPTAT into node 11b.

Thus, the compensated Zener voltage, V_{zener_comp}, results:

$${V}_{zener\_comp} = {V}_{zener} * ( \frac{Ry}{Rx + Ry} ) - {I}_{PTAT} \cdot k \cdot ( \frac{Ry * Rx}{Rx + Ry} )$$

It can be approximated to the expression below since Ry>>Rx:

$${V}_{zener\_comp} = {V}_{zener} - Δ {V}_{X} = {V}_{zener} - {I}_{PTAT} \cdot k \cdot {R}_{X}$$

i.e., it depends on the Zener voltage V_{Zener} and the temperature compensation voltage, ΔV_{X}, specifically on their difference, since the voltage divider 12 is in a mesh with the Zener diode 14, thus the lower leg of the divider 12 is the difference of the Zener voltage V_{Zener} and the temperature compensation voltage, ΔV_{X}. The compensation voltage, ΔV_{X}, is the voltage drop on the compensation resistor R_{X}, generated by the current IPTAT by the mirroring factor k.

In FIG. 2 it is shown a further embodiment 20 of a Zener voltage reference, which includes also an output buffer which output is coupled to the load.

As shown the PTAT module 11 and the bias current generator 15 and the Zener 13 are coupled in the same way as in circuit 10 of FIG. 1. A divider 22 comprising Rₓ, R_{y1}, R_{y2} is coupled here to the PTAT module 11. The output 11a is also coupled in the same to way to resistor Rₓ, while resistor R_{y} is here divided in two resistor R_{y} coupled to node 11b and resistor Rₓ and resistor R_{y2} coupled to a reference ground GND, i.e., a ground reference of the Zener voltage reference, On node 11b is formed the compensated Zener voltage, V_{zener_comp} as before, while on the common node 11c between resistors R_{y1}, R_{y2} is taken a reference Zener voltage, V_{zener_ref}, which is of course proportional to the compensated Zener voltage V_{zener_comp}. An output buffer amplifier 21 receives the reference Zener voltage, V_{zener_ref} at its positive input, which output is coupled to the gate of a MOSFET 23 having a load L coupled between its drain and supply voltage VBAT. The source, to which is coupled the feedback path of the buffer amplifier 21 is coupled through a feedback resistance R_{feedbak} to a local ground LGND.

As said, the resistance Rₓ on which the compensation voltage is taken is much smaller than R_{y} or R_{y}1+R_{y2}, e.g., at least ten times smaller in order for the approximation

$${V}_{zener\_comp} = {V}_{zener} - Δ {V}_{X} = {V}_{zener} - {I}_{PTAT} \cdot k \cdot {R}_{X}$$

to be correct. By way of example, values of resistor Rₓ could be 7.7 kOhm, R_{y1} 376 kOhm and R_{y2} 140 kOhm, although of course different choices and values and their ratios are possible.

The compensated voltage, e.g., V_{zener_comp}, is further partitioned to get a reference V_{zener_ref} comparable to a bandgap voltage level. Successively, this voltage is buffered and used to generate a reference current I_{ref_ideal} for the load L, i.e., a circuit using the reference current, that in case of BMS (Battery Management System) may correspond to an ADC converter:

$${I}_{ref\_ideal} = \frac{{V}_{zener\_ref}}{{R}_{feedbak}}$$

The reference ground RGND of the Zener is different from the local ground LGND due to the presence of a metal connection, indicated by the resistor Rₘₑₜₐₗ, which introduces and additional voltage drop. As results the reference current I_{ref_ideal} will be affected by a nonnegligible error.

This problem worsens if n loads (20 ADC in the case of a BMS device which may be an exemplary application of the voltage reference circuit here described) are connected to the reference and they share the same ground connection. With reference to FIG. 3, where n loads L1, Ln are shown coupled to respective amplifiers 21 driven each by the reference V_{zener} ref from the circuit 20, each with a respective reference current I_{ref_i}, assuming all the feedback resistances R_{feedbak} equal:

$${I}_{ref\_i} = \frac{{V}_{zener\_ref}}{{R}_{feedbak} + n \cdot {R}_{metal}} \to {I}_{err} = {I}_{ref\_i} - {I}_{ref\_ideal} \approx - \frac{n \cdot {R}_{metal}}{{R}_{feedbak}}$$

As a consequence, a dedicated path must be done to each load, resulting in a much more complicated layout routing.

Mirroring just a single current cannot be done due to the matching required between the resistance R_{feedbak} and the resistance of the loads.

### SUMMARY

An object of one or more embodiments is to contribute in dealing with a number of issues which are recognized to exist in a context as discussed in the foregoing.

According to one or more embodiments that object may be achieved by a Zener voltage reference circuit having the features set forth in the claims that follow.

As mentioned previously, various embodiments of the present disclosure regard a voltage reference circuit for supplying a reference voltage (comprising a Zener circuitry configured to generate a Zener voltage and a temperature compensation circuit arrangement configured to supply at its output a temperature depending current, in particular a PTAT current, to a Zener voltage compensation circuit comprising a compensation resistor, receiving the temperature depending current, on which a compensation voltage is formed, the voltage reference circuit being configured to supply an output voltage which depends on the Zener voltage and the temperature compensation voltage, wherein the voltage reference circuit (is configured to supply the output voltage as differential voltage between a first voltage and a second voltage, at least one of the first voltage and second voltage being taken from the Zener voltage compensation circuit.

In variant embodiments, the differential voltage is coupled to a differential buffer architecture which differential output is coupled to a feedback resistor to generate a reference current.

In variant embodiments, the Zener voltage compensation circuit comprises a voltage divider arranged in parallel to the Zener circuitry, the voltage divider comprising the compensation resistor coupled between the outputs of the compensation circuitry, and a further divider coupled between the compensation resistor and ground, comprising a middle resistive circuitry coupled to the compensation resistor and ground by further respective resistive circuitries on the terminals of the middle resistive circuitry being taken the first voltage and second voltage of the differential voltage.

In variant embodiments, the Zener voltage compensation circuit comprises the compensation resistor coupled between a temperature compensated current generator generating the temperature depending current and ground, forming the compensation voltage with reference to the ground voltage, the compensation voltage and Zener voltage being taken as the first voltage and second voltage of the differential voltage.

In variant embodiments, the Zener voltage compensation circuit comprises the compensation resistor coupled between a temperature compensated current generator generating the temperature depending current and ground and a further voltage divider coupled between the Zener voltage and the node receiving the temperature depending current, the further voltage divider comprising a middle resistive circuitry coupled the Zener voltage and the node receiving the temperature depending current by further respective resistive circuitries, on the terminals of the middle resistive circuitry being taken the first voltage and second voltage of the differential voltage.

In variant embodiments, the Zener circuitry comprises at least a Zener diode and a bias current generator to bias the at least a Zener diode.

In variant embodiments, the differential buffer architecture includes an instrumental amplifier.

In variant embodiments, the differential buffer architecture which differential output is coupled to a feedback resistor comprises two differential branches comprising a respective buffer amplifier each comprising a transistor at its output, in particular a MOSFET, which output electrode is coupled on either terminal of the feedback resistance, a reference current being taken as the current flowing through the transistors, in particular on the other electrode of transistor not coupled to the feedback resistance or to a supply terminal.

In variant embodiments, the temperature compensation circuit arrangement comprises a temperature compensated current generator, in particular PTAT compensated, coupled to an arrangement of current mirrors to mirror the temperature depending current to the outputs of the temperature compensation circuit arrangement with a mirroring ratio equal or greater than one to obtain the current proportional or equal to the temperature depending current.

The claims are an integral part of the technical disclosure of the embodiments as provided herein.

### BRIEF DESCRIPTION OF THE DRAWINGS

One or more embodiments will now be described, by way of example only, with reference to the annexed figures, wherein:

FIG. 1 shows a voltage reference circuit;

FIG. 2 shows a voltage reference circuit with an output buffer having an output coupled to a load;

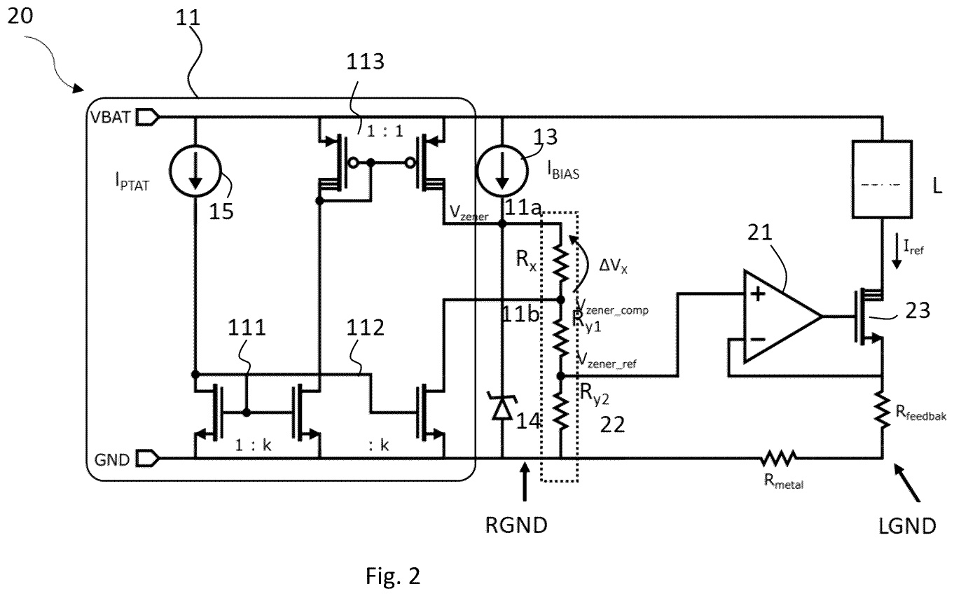

FIG. 3 shows a voltage reference circuit with multiple output buffers and loads;

FIG. 4 shows a circuit diagram of a first embodiment of a voltage reference circuit;

FIG. 5 shows a circuit diagram of a second embodiment of a voltage reference circuit; and

FIG. 6 shows a circuit diagram of a third embodiment of a voltage reference circuit.

### DETAILED DESCRIPTION OF ILLUSTRATIVE EMBODIMENTS

In the ensuing description, one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment. Moreover, particular conformations, structures, or characteristics may be combined in any adequate way in one or more embodiments.

The references used herein are provided merely for convenience and hence do not define the extent of protection or the scope of the embodiments.

The description relates to a voltage reference circuit comprising a Zener circuitry generating a Zener voltage, and a temperature compensation network configured to supply on its output a compensation current compensated for the temperature generated by a temperature compensated current generator, in particular PTAT compensation being carried out, the output being coupled to a resistive circuitry in parallel to the Zener circuitry, the resistive circuitry comprising a compensation resistor receiving the compensation current to form a compensation voltage, the resistive circuitry being configured to compensate the Zener voltage with the compensated voltage to obtain a Zener voltage reference circuit output voltage.

One or more embodiments herein described, in order to solve the problem given by the reference ground of the Zener being different from the local ground due to the metal connection, introducing a nonnegligible error on the reference current supplied at the load, include a voltage reference circuit for supplying a reference voltage comprising a Zener circuitry configured to generate a Zener voltage and a temperature compensation circuit arrangement configured to supply at its output a temperature depending current, in particular a PTAT current, to a Zener voltage compensation circuit comprising a compensation resistor, receiving such temperature depending current, on which a compensation voltage is formed.

The voltage reference circuit is configured to supply an output voltage that depends on the Zener voltage and the temperature compensation voltage, in which such voltage reference circuit is configured to supply such output voltage as differential voltage between a first voltage and a second voltage, at least one of such first voltage and second voltage being taken from such Zener voltage compensation circuit.

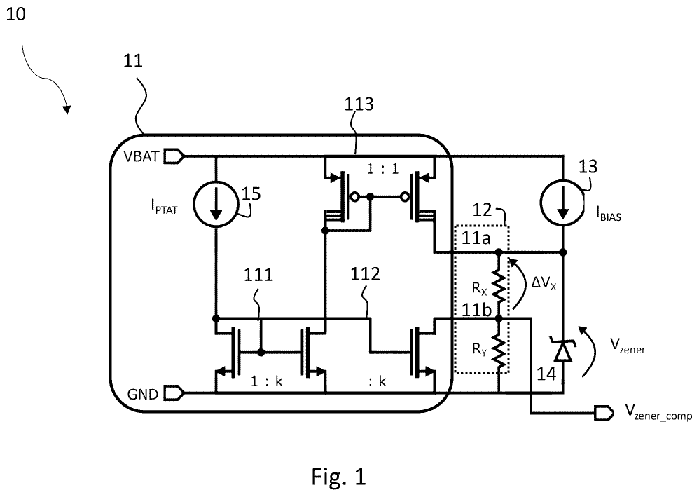

Thus, in a first exemplary embodiment, with reference to the circuit, e.g., of FIG. 1, the lower resistances in the divider 12, e.g., resistor R_{y} coupled to ground, are split to obtain a differential voltage V_{zener_ref} a voltage from the Zener voltage V_{zener_comp}.

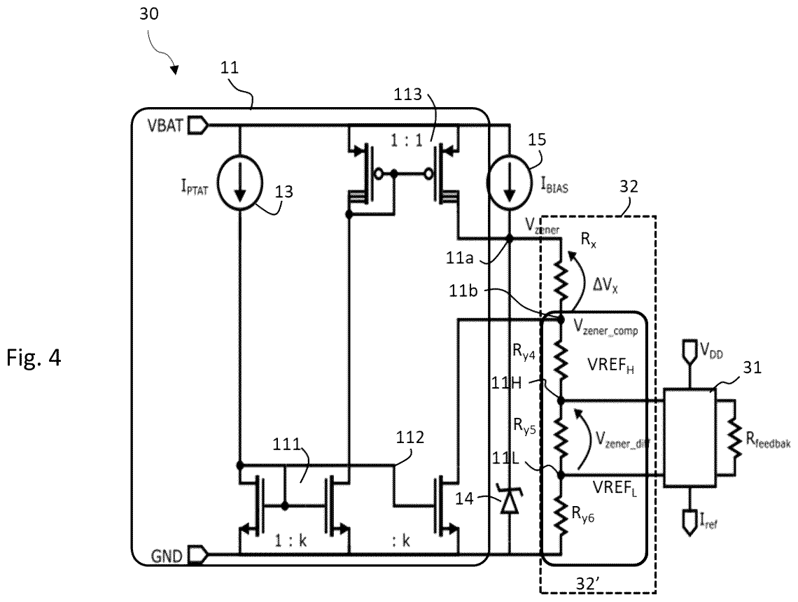

As said, the Zener reference circuit 30 of FIG. 4 presents the same circuit of FIG. 1, with the exception of the resistor R_{y} coupled to ground GND, in a voltage divider here indicated with 32, in place of divider 12.

Thus, the Zener reference circuit 30, which can operate as voltage regulator, comprises the temperature compensation circuit, in particular PTAT module, 11, which comprises the PTAT mirrors 111, 112, 113 mirroring the current of the PTAT current generator 15 supplying the PTAT current IPTAT, coupled between a supply voltage, in particular a battery voltage VBAT, and a ground reference GND and has its two terminal outputs 11a and 11b coupled to a Zener voltage compensation circuit embodied by a voltage resistive divider 32, which comprises the first resistor, a compensation resistor Rₓ, on which is formed the PTAT voltage compensation, ΔV_{X}.

The PTAT current generator 15 may be obtained in general by a circuit arrangement producing a PTAT current IPTAT which is circuit arrangement which includes a pair of bipolar transistors or MOSFETs, e.g., in which flows the same current, and which current is substantially

$${I}_{PTAT} = \frac{VT * ln ( m )}{R} ,$$

m being the ratio of the emitter areas of the bipolar transistors or the width ratio of the MOSFETs channels, VT is the thermal voltage, and R a resistor in series to the source of the bigger bipolar or MOSFET.

The output 11a of the PTAT module 11 is coupled to a terminal of the first resistor Rx. As shown in FIG. 4, to the output node 11b of the PTAT module 11 is coupled to the divider 32, which comprises the same upper leg formed by resistor Rₓ coupled to output 11a, the lower leg being formed by splitting the resistor R_{y} of FIG. 1 in a further divider 32′, comprising three resistors in series, a first resistor R_{y4}, coupled to resistor Rₓ, in series with a second, or middle, resistor R_{y5} and a third resistor R_{y6} coupled to reference ground GND. A Zener circuitry generating a Zener voltage V_{zener} comprises the bias current generator 13 supplying a bias current I_{BIAS} to the Zener diode 14 and coupled between the supply voltage VBAT and output 11a, and the Zener diode 14, coupled between the output 11b and ground GND, the Zener voltage drop V_{zener} occurring on the Zener diode 14. Clearly the Zener circuitry may be obtained with different arrangements and circuit, comprising other Zener diodes and other components, as long as it determines a Zener voltage drop between the nodes, e.g., 11b and ground GND, to which is coupled. On the compensation resistor Rₓ forms the voltage drop, or PTAT voltage compensation ΔV_{X}, which is originated from the PTAT current IPTAT. The current mirrors 111, 112 in parallel receive the current IPTAT and have 1:k mirroring ratio, with k integer value equal or greater than one. The first mirror PMR1, with n-MOSFET type transistors coupled to ground GND, repeats the current to a mirror 113, p-MOSFET type transistors coupled to voltage supply VBAT with 1:1 mirroring ratio, which serves to mirror the current into node 11a. Mirror 112, also n-type, mirrors the PTAT current IPTAT into node 11b.

Thus, since the Zener voltage compensation circuit, in the example a resistive circuitry, formed by the voltage divider 12, i.e., resistors Rx, Ry is configured to subtract the compensated voltage ΔV_{X} from the Zener voltage V_{Zener}, i.e., it is configured so that the compensated voltage ΔV_{X} is in a mesh with the Zener voltage V_{Zener} so that it is subtracted from such the Zener voltage V_{Zener}, the compensated Zener voltage, V_{zener_comp}, on node 11a is still:

$${V}_{zener\_comp} = {V}_{zener} - Δ {V}_{X} = {V}_{zener} - {I}_{PTAT} \cdot k \cdot {R}_{X}$$

in the approximation with Ry>>Rx.

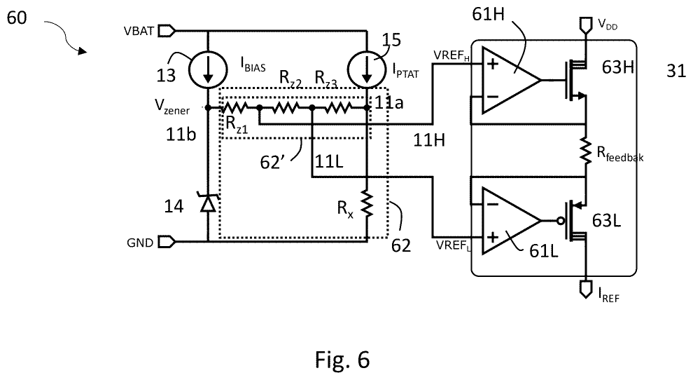

Then, differential output nodes 11H and 11L are formed on the terminals of middle resistor R_{y5}, respectively the one coupled to the first resistor R_{y4} and the one coupled to the third resistor R_{y6}. The resulting differential voltage V_{zener_diff} formed between a first voltage VREFH and a second voltage VREFL, i.e., differential voltage components, on such differential nodes 11H and 11L is still buffered to a feedback resistance R_{feedbak} to generate the reference current I_{ref}. A differential block 31, is configured to perform the buffering and supplying the reference current I_{ref}. The differential block 31 comprises for instance a differential buffer architecture 31 which differential output is coupled to a feedback resistor R_{feedbak}, receiving the differential components VREFH and VREFL of the differential reference voltage V_{zener_diff}. In embodiments, the differential block 31 can be coupled, in particular in the output MOSFET, to a low voltage supply V_{DD}. The other elements components correspond to those with corresponding reference in the circuit of FIG. 1. An example of implementation of the differential buffer architecture 31 is described in the following with reference to FIG. 6.

It is noted that the Zener voltage compensation circuit comprises a further divider 32′ in the divider 32, coupled between the compensation resistor Rₓ and ground GND, comprising a middle resistive circuitry, which in this case is embodied only by the middle resistor R_{y5}, but can be embodied by other equivalent circuit arrangements, e.g., an arrangement of resistors or components with the same equivalent resistance, coupled to the compensation resistor Rₓ and ground GND by further respective resistive circuitries, again in this case resistors R_{y4}, R_{y6}, but other arrangements are possible, on the terminal of the middle resistive circuitry, R_{y5}, being taken the differential voltage V_{zener_diff}, i.e., first voltage VREFH and a second voltage VREFL.

Alternatively, in this and other embodiments the temperature compensation module may include a temperature dependent generator 15, which is a CTAT (Complementary To Absolute Temperature) current generator, rather than a PTAT. As in the CTAT the temperature coefficient is opposite to the PTAT, clearly the circuit is to be rearranged to sum the voltage compensation ΔV_{X}, obtained by applying the current from a CTAT current generator to a resistor, to the Zener voltage rather than subtract it, for example directly connecting the current generator 15 to node 11b of FIG. 1.

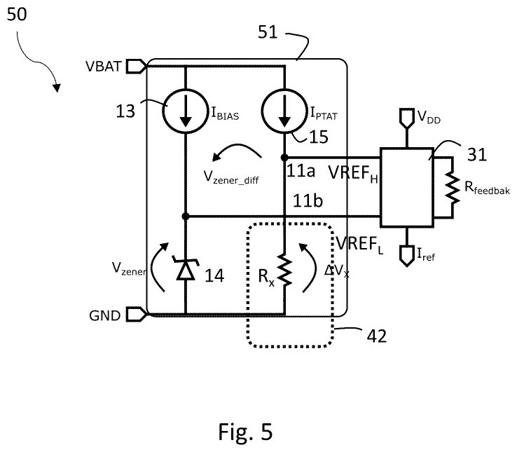

In FIG. 5 is shown a further embodiment 50 of the circuit according to the solution here described comprising a different temperature compensation module, in particular a PTAT module 51 configured with a Zener voltage compensation circuit embodied by a resistive circuitry 42, in particular comprising the sole compensation resistor Rₓ, to generate the PTAT voltage compensation ΔV_{X} from the bottom resistance, avoiding current mirroring of the PTAT CURRENT IPTAT.

As shown in FIG. 5, the series of bias current generator 13 and Zener diode 14, coupled between supply voltage VBAT and ground GND, is maintained. The PTAT current generator 15 in series with a compensation resistor Rₓ is coupled between supply voltage VBAT and reference ground RGND, while the differential block 31 is coupled to nodes 11a, i.e., the terminal of the compensation resistor Rₓ receiving the PTAT current IPTAT, in this case not mirrored and thus substantially corresponding, i.e., equal to the current from the generator, and node 11b, i.e., the node coupled to the node in common between the bias current generator 13 and Zener diode 14. Node 11a and 11b correspond to differential nodes 11H and 11L in the previous embodiments, on which the differential reference voltage V_{zener_diff} is taken. As indicated the differential block 31 comprises for instance a differential buffer, in particular a voltage follower arrangement with an operational amplifier, receiving the differential components VREFH and VREFL of the differential reference voltage V_{zener_diff}. In this case the compensation resistor Rₓ alone embodies the resistive circuitry 42 on which the other component of the differential reference voltage V_{zener_diff} along with the Zener voltage V_{zener}.

In this embodiment, without the NMOS mirror, e.g., 111, 112, in the temperature compensation circuit arrangement, e.g., PTAT module, of the other embodiments, the low frequency noise (RTN) reduces, as observed for instance in BCD9S technology. If differential nets, i.e., referred to the first voltage VREFH and second voltage VREFL, are placed close to each other, external disturbances become common mode and are canceled by the differential mechanism.

In FIG. 6 it is shown a further embodiment 60 of the Zener reference voltage, in which the differential voltage generated is further divided by a further voltage divider 62′ to adapt its level to external circuits.

In this embodiment it is shown the topology of the differential block 31, which comprises an instrumental amplifier topology, in a voltage follower configuration which can be used as buffer to generate the reference current I_{REF}. This circuitry can be realized with CMOS5V technology and supplied with a low voltage supply V_{DD}.

As shown in FIG. 6, like in FIG. 5 the reference voltage circuit 60 comprises the series of bias current generator 13 and Zener diode 14, coupled between the supply voltage VBAT and ground GND, and the PTAT current generator 15 in series with the compensation resistor Rₓ coupled between supply voltage VBAT and ground GND. The output node 11b is however coupled to the output node 11a by a further divider 62′, comprising three resistors R_{z1}, R_{z2}, R_{z3} in series, on the differential terminals 11H, 11L of the middle resistor R_{z2} is taken a differential output, i.e., the differential components VREFH and VREFL of the differential reference voltage V_{zener_diff}. The further divider 62′ along with the compensation resistor forms a divider 62. The differential components VREFH and VREFL of the differential reference voltage V_{zener_diff} are sent to the positive input of respective buffers 61H and 61L in the differential block 31. The buffers 61H and 61L drive respective n output MOSFET 63H and p output MOSFET 63L, from which source a feedback path, e.g., a short circuit path according to the voltage follower configuration, is coupled to their respective negative input. The n output MOSFET 63H has its drain coupled to the digital supply voltage V_{DD} and the source to the feedback path of the buffer 63H and to the feedback resistance R_{feedbak}. MOSFET 63L dually is coupled by the source to the feedback resistance R_{feedbak} and to the feedback path of buffer 42L and on its drain supplies the reference current I_{ref}. This architecture of the differential block 31 is an example of a possible implementation of such block, although other differential topologies are possible, e.g., since the topology has to be able to buffer the differential voltage reading it in a high impedance, such differential topologies may obtain a function of an INA (Instrumentation Amplifier). The transistor, bipolar or field effect, in particular MOSFET, on the output of the voltage follower in the feedback path as described is known also as boost transistor.

Also in this case equivalent resistive circuitries may be used in place of the three resistors R_{z1}, R_{z2}, R_{z3}, to form such further resistive divider 62′ comprising a middle resistive circuitry R_{z2} coupled the Zener voltage and the node 11a receiving the compensation current IPTAT by further respective resistive circuitries R_{z1}, R_{z2}, on the terminals of the middle resistive circuitry R_{z2} being taken the differential voltage V_{zener_diff} or VREFH, VREFL.

Thus, the solution here described refers to a voltage reference circuit such as circuits 30, 40, 50 for supplying a reference voltage comprising a Zener circuitry, e.g., components 13, 14 generating a Zener voltage, V_{zener}, and a temperature compensation circuit arrangement, e.g., the circuit arrangement 11 with current mirroring or the circuit arrangement 51 without current mirrors, comprising a generator, e.g., 15 generating a temperature depending current, e.g., the current IPTAT, in particular a PTAT current for instance from a PTAT bandgap reference, and supplying at its output, 11a, 11b, a current proportional or equal to the temperature depending current, IPTAT, e.g., proportional through mirrors with a given mirroring ratio, i.e., k, or the current IPTAT itself in circuits 50, 60, to a Zener voltage compensation circuit, e.g., the voltage divider 32 or the other resistive circuits 42, 62, comprising a compensation resistor, Rₓ, receiving the current proportional or equal to the temperature depending current (IPTAT), on which a compensation voltage (ΔV_{X}) is formed.

The voltage reference circuit, e.g., 30; 50; 60, being configured to supply an output voltage, e.g., V_{zener_diff}, which depends on the Zener voltage, V_{Zener} and the temperature compensation voltage, ΔV_{X}, e.g., configured to form a mesh with the Zener diode so that a difference between the Zener voltage, V_{Zener} and the temperature compensation voltage, ΔV_{X}, forms on the other leg of the voltage divider or configure to directly take the voltages VREFH, VREFL from the Zener voltage, V_{Zener} and the temperature compensation voltage, ΔV_{X}.

The voltage reference circuit, e.g., 30 or 50 or 60, is configured to supply the output voltage V_{zener_diff} as differential voltage between a first voltage VREFH and a second voltage VREFL, at least one of the first voltage VREFH and second voltage VREFL being taken from the Zener voltage compensation circuit, 32 or 42 or 62, e.g., depending on or corresponding to the temperature compensation voltage, ΔV_{X}.

In other words, the solution here described provides a Zener reference voltage with the arrangement just described which provides as output a differential voltage obtained from the Zener voltage and the temperature compensation voltage, ΔV_{X}.

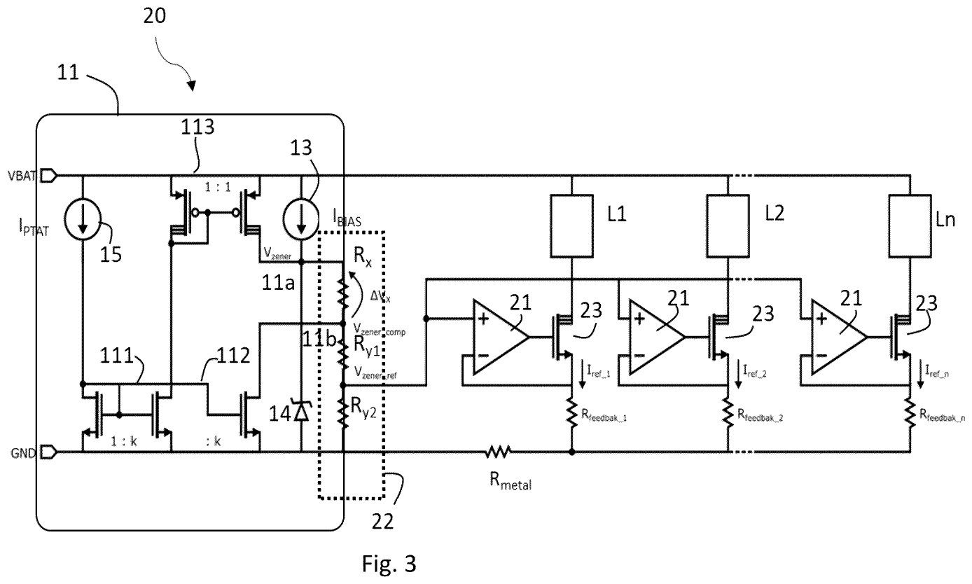

Then, such differential voltage can be buffered to obtain a reference current (or many reference currents with the buffer arrangement of FIG. 3), thus the solution also refers to a Zener voltage reference circuit, e.g., 30 or 50 or 60, wherein such differential voltage V_{zener_diff}, VREFH, VREFL is coupled to a differential buffer architecture 31 which differential output is coupled to a feedback resistor R_{feedbak} to generate a reference current I_{REF}.

The Zener voltage compensation circuit may be embodied in the Zener voltage reference circuit, e.g., circuit 30, comprising comprises a divider, e.g., 32, arranged in parallel to the Zener circuitry, 13, 14, comprising the compensation resistor Rₓ coupled between the outputs, 11a, 11b, of the compensation circuitry, e.g., 11, and a further divider, 32′, coupled between such compensation resistor, Rₓ, and ground, GND, comprising a middle resistive circuitry, e.g., R_{y5}, coupled to such compensation resistor, Rₓ, and ground, GND by further respective resistive circuitries, e.g., R_{y4}, R_{y6}, on the terminal of the middle resistive circuitry being taken as the first voltage, VREFH, and second voltage, VREFL, of the differential voltage, V_{zener_diff}.

Also the resistive circuitry 42 may be embodied in the Zener voltage reference circuit, e.g., circuit 50, comprising the compensation resistor Rₓ coupled between the temperature compensated current generator 15 and ground GND, forming the compensation voltage, ΔV_{X}, with reference to the ground GND voltage, i.e., in the resistive leg, the sole in this case, coupled, in particular directly connected, to ground, such differential voltage being taken as the first voltage, VREFH, and second voltage, VREFL, of the differential voltage, V_{zener_diff}.

Also the resistive circuitry, 62, may be embodied in the Zener voltage reference circuit, e.g., circuit 60, comprising such compensation resistor Rₓ coupled between the temperature compensated current generator 15 and ground GND and a further resistive divider, e.g., 62′, coupled between the Zener voltage and the node 11a receiving the compensation current I_{PTAT}, the further resistive divider comprising a middle resistive circuitry, e.g., resistor R_{z2}, coupled the Zener voltage and the node 11a receiving the compensation current I_{PTAT} by further respective resistive circuitries, e.g., resistors R_{z1}, R_{z2}, on the terminals of the middle resistive circuitry, e.g., R_{z2}, being taken the first voltage, VREFH, and second voltage, VREFL, of the differential voltage, V_{zener_diff}.

As indicated in the exemplary embodiments the Zener circuitry comprises at least a Zener diode and a bias current generator 13 to bias the at least a Zener diode 14, although other Zener voltage providing circuits may also be implemented.

The differential buffer architecture 31 which differential output is coupled to a feedback resistor R_{feedbak} may comprise two differential branches comprises a buffer amplifier, e.g., 61H, 61L, each comprising a transistor circuit, in particular a MOSFET, 63H, 63L, which output is coupled on either terminal of the feedback resistance, e.g., R_{feedbak}, a reference current I_{ref} being taken as the current flowing through the transistors 63H, 63L, in particular on the other electrode of transistor 63L not coupled to the feedback resistance or to a supply terminal, in particular on the drain of the MOSFET 63L.

As mentioned, in embodiment the temperature compensation network 11 may comprises the temperature compensated current generator 15, in particular PTAT compensated, coupled to an arrangement of current mirrors, 111, 112, 113, to mirror the temperature compensated current to the outputs 11a, 11b of the temperature compensation circuitry, 11, with a mirroring ratio, e.g., k, equal or greater than one to obtain the current proportional or equal to the temperature depending current I_{PTAT}.

As indicated circuits 50, 60 include a temperature compensation circuitry 51 without current mirrors.

The generator, e.g., 15, generating a temperature depending current, in the example I_{PTAT}, is configured to generate a PTAT current. In variant embodiment the generator generating a temperature depending current may generate a CTAT current. In this case the circuit may adjusted, e.g., the generator may be arranged to output the current.

From the description here above thus the advantages of the solution described are clear.

Advantageously, the solution here described thus, by the differential reference circuit described generates a high precision voltage reference, avoiding ground shift effect with less layout routing complexity.

In embodiments, the described solution here described has a lower scaling factor, e.g., from the Zener voltage V_{zener} to the differential voltage, VREFH-VREFL.

Also, there is no longer metal connection, e.g., Rₘₑₜₐₗ, contribution, which makes it easier for routing.

Also, in embodiments, there is less noise due to mirroring.

Buffers can be realized in CMOS5V technology.

Without prejudice to the underlying principles, the details and embodiments may vary, even significantly, with respect to what has been described by way of example only, without departing from the extent of protection.

The extent of protection is defined by the annexed claims.

What is claimed is:

1. A voltage reference circuit for supplying a reference voltage, the voltage reference circuit comprising:
a Zener circuitry configured to generate a Zener voltage; and
a temperature compensation circuit comprising a temperature compensated current generator configured to generate a temperature-depending current, and supply at its output a current proportional or equal to the temperature-depending current to a Zener voltage compensation circuit comprising a compensation resistor configured to receive the current proportional or equal to the temperature-depending current, on which a compensation voltage is formed;
wherein the voltage reference circuit is configured to supply an output voltage that depends on the Zener voltage and the compensation voltage; and
wherein the output voltage is a differential voltage between a first voltage and a second voltage, at least one of the first voltage and second voltage taken from the Zener voltage compensation circuit.

2. The voltage reference circuit according to claim 1, wherein the differential voltage is coupled to a differential buffer architecture having a differential output coupled to a feedback resistor to generate a reference current.

3. The voltage reference circuit according to claim 1, wherein the Zener voltage compensation circuit comprises a voltage divider arranged in parallel to the Zener circuitry, the voltage divider comprising the compensation resistor coupled between outputs of the Zener voltage compensation circuit, and a further divider, coupled between the compensation resistor and a ground, comprising a middle resistive circuitry coupled to the compensation resistor and the ground by further respective resistive circuitries on terminals of the middle resistive circuitry taken from the first voltage and the second voltage of the differential voltage.

4. The voltage reference circuit according to claim 1, wherein the Zener voltage compensation circuit comprises the compensation resistor coupled between the temperature compensated current generator configured to generate the temperature-depending current and a ground, forming the compensation voltage with reference to a ground voltage, the compensation voltage and the Zener voltage being taken as the first voltage and the second voltage of the differential voltage.

5. The voltage reference circuit according to claim 1, wherein the Zener voltage compensation circuit comprises the compensation resistor coupled between the temperature compensated current generator configured to generate the temperature-depending current and a ground, and a further voltage divider coupled between the Zener voltage and a node receiving the temperature-depending current, the further voltage divider comprising a middle resistive circuitry coupled to the Zener voltage and the node receiving the temperature-depending current by further respective resistive circuitries, on terminals of the middle resistive circuitry taken from the first voltage and the second voltage of the differential voltage.

6. The voltage reference circuit according to claim 1, wherein the Zener circuitry comprises at least one Zener diode and a bias current generator to bias the at least one Zener diode.

7. The voltage reference circuit according to claim 2, wherein the differential buffer architecture includes an instrumental amplifier.

8. The voltage reference circuit according to claim 2, wherein the differential output of the differential buffer architecture comprises two differential branches, each branch comprising a respective buffer amplifier comprising a transistor at an output electrode that is coupled on either terminal of the feedback resistor, wherein the reference current is a current flowing through the transistors.

9. The voltage reference circuit according to claim 8, wherein each transistor is a metal-oxide-semiconductor field effect transistor (MOSFET).

10. The voltage reference circuit according to claim 8, wherein the reference current is taken as the current flowing on another electrode of the transistor not coupled to the feedback resistor or to a supply terminal.

11. The voltage reference circuit according to claim 1, wherein the temperature compensation circuit comprises the temperature compensated current generator coupled to an arrangement of current mirrors to mirror the temperature-depending current to the output of the temperature compensation circuit with a mirroring ratio equal to or greater than one to obtain the current proportional or equal to the temperature-depending current.

12. The voltage reference circuit according to claim 1, wherein the temperature-depending current is a proportional to absolute temperature (PTAT) current.

13. A method of supplying a reference voltage by a voltage reference circuit, the method comprising:
generating, by a Zener circuitry, a Zener voltage;
generating, by a temperature compensated current generator of a temperature compensation circuit, a temperature-depending current;
supplying, by the temperature compensated current generator at its output, a current proportional or equal to the temperature-depending current to a Zener voltage compensation circuit;
receiving, by a compensation resistor of the Zener voltage compensation circuit, the current proportional or equal to the temperature-depending current;
forming, on the compensation resistor, a compensation voltage; and
supplying, by the voltage reference circuit, an output voltage that depends on the Zener voltage and the compensation voltage, the output voltage being a differential voltage between a first voltage and a second voltage, at least one of the first voltage and second voltage taken from the Zener voltage compensation circuit.

14. The method according to claim 13, further comprising, generating a reference current by a feedback resistor coupled to a differential output of a differential buffer architecture coupled to the differential voltage.

15. The method according to claim 14, wherein the differential buffer architecture includes an instrumental amplifier.

16. The method according to claim 14, wherein the differential output of the differential buffer architecture comprises two differential branches, each branch comprising a respective buffer amplifier comprising a transistor at an output electrode that is coupled on either terminal of the feedback resistor, and the method further comprises using a current flowing through the transistors as the reference current.

17. The method according to claim 13, further comprising forming, by the compensation resistor coupled between the temperature compensated current generator and a ground, the compensation voltage with reference to a ground voltage, the compensation voltage and the Zener voltage being taken as the first voltage and the second voltage of the differential voltage.

18. The method according to claim 13, wherein the Zener circuitry comprises at least one Zener diode and a bias current generator, and the method further comprises biasing, by the bias current generator, the at least one Zener diode.

19. The method according to claim 13, further comprising mirroring, by an arrangement of current mirrors coupled to the temperature compensated current generator, the temperature-depending current to the output of the temperature compensation circuit with a mirroring ratio equal to or greater than one to obtain the current proportional or equal to the temperature-depending current.

20. The method according to claim 13, wherein the temperature-depending current is a proportional to absolute temperature (PTAT) current.
